(19) United States
(12) Patent Application Publication
(10) Pub. No.: US 2022/0318591 A1
(43) Pub. Date: Oct. 6, 2022

(54) INFERENCE METHOD AND INFORMATION PROCESSING APPARATUS

(71) Applicant: FUJITSU LIMITED, Kawasaki-shi (JP)

(72) Inventors: AMIR HADERBACHE, Kawasaki (JP); Koichi SHIRAHATA, Yokohama (JP)

(73) Assignee: FUJITSU LIMITED, Kawasaki-shi (JP)

(21) Appl. No.: 17/549,934

(22) Filed: Dec. 14, 2021

(30) Foreign Application Priority Data
Apr. 2, 2021 (JP) 2021-063522

(51) Int. Cl. G06N 3/04

(52) U.S. Cl. CPC G06N 3/04

(57) ABSTRACT

A memory stores a first trained model for determining features of mesh data, which includes a plurality of nodes and a plurality of edges connecting them, by removing some of the edges from the mesh data. A processor generates, from second mesh data, first mesh data having a smaller number of edges than the second mesh data by use of the first trained model. The processor generates, by running a simulation using the first mesh data, first simulation result data that indicates a physical quantity of an object represented by the first mesh data. The processor infers, from the first mesh data and the first simulation result data and by use of a second trained model, second simulation result data that would be obtained by running the simulation using the second mesh data.

### CROSS-REFERENCE TO RELATED APPLICATION

This application is based upon and claims the benefit of priority of the prior Japanese Patent Application No. 2021-063522, filed on Apr. 2, 2021, the entire contents of which are incorporated herein by reference.

### FIELD

The embodiments discussed herein relate to an inference method and information processing apparatus.

### BACKGROUND

Simulations are used to analyze physical characteristics of objects based on the shapes of the objects. Such simulations include, for example, structural analyses for calculating stress and displacement, fluid analyses for calculating flow velocity and fluid density, and electromagnetic analyses for calculating electric current and magnetic force. Some simulations use mesh data including discrete nodes and edges connecting them as configuration data representing geometrical shapes of objects. In addition, simulations may employ numerical analyses, such as finite element methods (FEM), to give approximate solutions to governing equations that model physical phenomena. For example, such a numerical analysis approach assigns variables to nodes, then generates a coefficient matrix representing the relationships between the nodes, and finds an approximate solution to a system of equations by an iterative method.

There is a proposed resolution control system that contracts vertex pairs included in a high-resolution mesh model to generate a low-resolution mesh model suitable for finite element analysis. There is also a proposed mesh correcting apparatus for grouping triangles included in a mesh model using a neural network and applying the same correction made to a given triangle to other triangles belonging to the same group. Furthermore, there is a proposed mesh generating apparatus for constructing a response surface using a representative shape model and a parameter indicating mesh resolution.

See, for example, Japanese Laid-open Patent Publication No. 2005-242647, Japanese Laid-open Patent Publication No. 2006-318232, and Japanese Laid-open Patent Publication No. 2011-243016.

With the use of fine mesh data with a large number of element regions, simulations face high computational complexity and thus take long time to complete while they produce highly accurate analysis results. In view of this, it is considered reasonable to run simulations using coarse mesh data with a small number of element regions and use the coarse simulation results to thereby infer fine simulation results that would be obtained in case of using fine mesh data. For the inference, a trained model built by machine learning, such as a neural network, may be used.

Note however that, in running simulations, it is sometimes the case that, although fine mesh data has already been created by the user, coarse mesh data corresponding to the fine mesh data is yet to be made. For example, in the case where the user checks physical properties of an industrial component using simulations after designing the component, there may be no coarse mesh model yet while design data, which is equivalent to a fine mesh model, has already been created.

### SUMMARY

According to one aspect, there is provided a non-transitory computer-readable recording medium storing therein a computer program that causes a computer to execute a process including: generating, from second mesh data, first mesh data having a smaller number of edges than the second mesh data by use of a first trained model for determining features of mesh data, which includes a plurality of nodes and a plurality of edges connecting the plurality of nodes, by removing some of the plurality of edges from the mesh data; generating, by running a simulation using the first mesh data, first simulation result data that indicates a physical quantity of an object represented by the first mesh data; and inferring, from the first mesh data and the first simulation result data and by use of a second trained model, second simulation result data that would be obtained by running the simulation using the second mesh data.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 illustrates an information processor according to a first embodiment;

FIG. 2 is a block diagram illustrating an example of hardware of an information processor according to a second embodiment;

FIG. 3 illustrates an example of stress prediction using a neural network;

FIG. 4 illustrates examples of fine and coarse mesh models;

FIG. 5 illustrates an example of a structure of a neural network;

FIG. 6 illustrates examples of parameters associated with a corner and a fillet;

FIG. 7 is a graph illustrating examples of speed magnification of stress prediction;

FIG. 8 illustrates a second example of stress prediction using the neural network;

FIG. 9 illustrates an example of a structure of a graph convolutional neural network (CNN);

FIG. 10 illustrates examples of inputs and outputs of the graph CNN;

FIG. 11 illustrates an example of stepwise pooling of a mesh model;

FIG. 12 illustrates examples of edge feature parameters;

FIG. 13 illustrates an example of edge removal by pooling;

FIG. 14 is a block diagram illustrating examples of functions of the information processor;

FIG. 15 illustrates examples of structures of mesh data and training data;

FIG. 16 is a flowchart illustrating an example of a procedure of machine learning processing; and

FIG. 17 is a flowchart illustrating an example of a procedure of a stress simulation.

### DESCRIPTION OF EMBODIMENTS

Several embodiments will be described below with reference to the accompanying drawings.

### 1. First Embodiment

A first embodiment is described hereinafter.

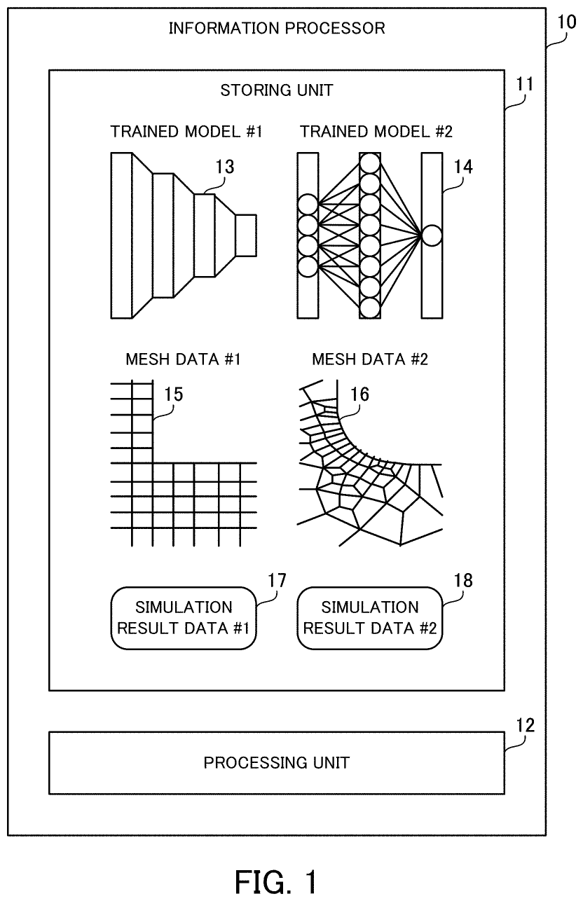

FIG. 1 illustrates an information processor according to the first embodiment.

An information processor 10 runs a simulation to analyze a physical characteristic of an object based on the shape of the object. Such a simulation may be a structural analysis for calculating stress and displacement, a fluid analysis for calculating flow velocity and fluid density, or an electromagnetic analysis for calculating electric current and magnetic force. The information processor 10 may be a client device or server device. The information processor 10 may be referred to, for example, as a computer, analyzer, or simulation device.

The information processor 10 includes a storing unit 11 and a processing unit 12. The storing unit 11 may be volatile semiconductor memory such as random access memory (RAM), or a non-volatile storage device such as a hard disk drive (HDD) or flash memory. The processing unit 12 is, for example, a processor such as a central processing unit (CPU), graphics processing unit (GPU), or digital signal processor (DSP). Note however that the processing unit 12 may include an electronic circuit designed for specific use, such as an application specific integrated circuit (ASIC) or field programmable gate array (FPGA). The processor executes programs stored in memory such as RAM. The term “multiprocessor”, or simply “processor”, may be used to refer to a set of multiple processors.

The storing unit 11 stores therein trained models 13 and 14 and mesh data 16.

The trained model 13 is a determination model for determining features of mesh data. The term mesh data here refers to configuration data representing a geometrical shape of an object and including a plurality of nodes and a plurality of edges connecting the nodes. Such mesh data may be called graph data. The trained model 13 simplifies the mesh data by removing some edges therefrom to thereby determine features of the mesh data. For example, the trained model 13 determines the type (class) of an object represented by the mesh data. The trained model 13 is generated through machine learning.

The trained model 13 may be a neural network, or a graph convolutional neural network (CNN) that performs convolution operations on mesh data. For example, the trained model 13 performs at least one set of a convolution operation for calculating a feature of each edge based on its positional relationship to neighboring edges and a pooling operation for removing some edges based on the calculated feature of each edge. In addition, the trained model 13 may include a plurality of pooling layers to reduce the number of edges in stages. For example, the trained model 13 includes a certain number of pairs of a convolution layer engaging in a convolution operation and a pooling layer engaging in a pooling operation.

The trained model 14 is an inference model for inferring a physical quantity of an object represented by mesh data. In the case of a structural analysis, such a physical quantity is, for example, stress or displacement at a critical location subjected to high stress, such as an angle or hole in the object. The trained model 14 is built through machine learning. The trained model 14 may be a neural network.

The trained model 14 uses, for example, parameters related to a shape represented by coarse mesh data with a small number of edges and parameters related to physical quantities calculated on the coarse mesh data, to thereby infer a target physical quantity that would be obtained on fine mesh data with a high number of edges. The trained model 14 is, in other words, a conversion model for converting coarse simulation result data into highly accurate simulation result data. The trained model 14 infers, for example, stress at a fillet by using parameters related to the shape of a sharp angle represented by a small number of edges and parameters related to stress acting at the sharp angle.

The mesh data 16 is fine mesh data having a higher number of edges than mesh data 15 to be described below. The mesh data 16 includes, for example, a fillet which is a rounded corner without vertices. A greater number of edges is used for the shape of a fillet than for the shape of a sharp angle. The mesh data 16 may be generated from design data of an industrial component or computer aided design (CAD) data using mesh generation software.

Instead of running a simulation directly on the mesh data 16, the processing unit 12 infers simulation result data 18 corresponding to the mesh data 16 by use of the trained models 13 and 14. The simulation result data 18 includes a physical quantity of the object represented by the mesh data 16, for example, stress acting at the fillet. The processing unit 12 may employ a numerical analysis approach, such as a finite element method (FEM), for a simulation. For example, the simulation assigns variables to nodes, then generates a coefficient matrix representing the relationships between the nodes, and finds an approximate solution to a system of equations by an iterative method involving repetitive matrix operations.

First, the processing unit 12 generates, from the mesh data 16, the mesh data 15 having a lower number of edges than the mesh data 16 by the use of the trained model 13. The lower edge count may result in converting the shape of the fillet into an angular shape being sharper than the fillet. At this time, the processing unit 12 may extract intermediate data generated in the trained model 13 in the process of causing features of the mesh data 16 to be determined. The processing unit 12 may extract the output of a pooling layer included in the trained model 13. The processing unit 12 may extract the output of an intermediate pooling layer amongst a plurality of pooling layers. For example, the processing unit 12 extracts the output of the second or third pooling layer amongst four pooling layers.

Once the mesh data 15 is generated, the processing unit 12 runs a simulation, such as a FEM, using the mesh data 15 and generates simulation result data 17 corresponding to the mesh data 15. The simulation result data 17 includes a physical quantity of the object represented by the mesh data 15, for example, stress acting at the sharp angle. Because the mesh data 15 includes a lower number of edges than that of the mesh data 16, the simulation run using the mesh data 15 has lower computational complexity and therefore takes less time to run.

Then, using the trained model 14, the processing unit 12 infers the simulation result data 18 from the mesh data 15 and the simulation result data 17. For example, the processing unit 12 generates input data including parameters corresponding to the mesh data 15 and parameters corresponding to the simulation result data 17, then feeds the input data to the trained model 14, and acquires an inference value output from the trained model 14.

As has been described above, the information processor 10 of the first embodiment uses the trained model 13 for determining features of mesh data by removing some edges therefrom to thereby convert the mesh data 16 with a high number of edges into the mesh data 15 with a low number of edges. The information processor 10 runs a simulation using the mesh data 15. Then, the information processor 10 infers, from the mesh data 15 and the simulation result data 17 corresponding to the mesh data 15, the simulation result data 18 corresponding to the mesh data 16.

In this manner, the information processor 10 generates the highly accurate simulation result data 18 corresponding to the fine mesh data 16. The simulation using the coarse mesh data 15 involves lower computational cost and is therefore fast compared with the case of using the fine mesh data 16. This reduces computational complexity to obtain the highly accurate simulation result data 18, which in turn shortens the run-time.

In addition, the information processor 10 automatically generates the coarse mesh data 15 corresponding to the fine mesh data 16 by use of the trained model 13. This eases the burden of creating the mesh data 15 separately from the mesh data 16, and the information processor 10 is, therefore, able to achieve fast inference of the simulation result data 18. For example, when the user designs the shape of an industrial component, the information processor 10 assists the user by inferring the simulation result data 18 if design data of the industrial component is available.

In order to determine features of mesh data, the trained model 13 has been trained in such a manner as to remove edges poorly related to the features. Therefore, the mesh data 15 generated by use of the trained model 13 is a favorable coarse mesh model that preserves fundamental features of the mesh data 16. As a result, the accuracy of the simulation result data 17 improves, which in turn increases the inference accuracy of the simulation result data 18.

### 2. Second Embodiment

Next described is a second embodiment.

An information processor 100 according to the second embodiment runs a structural analysis simulation using a FEM and calculates stress according to the shape of an object. The information processor 100 also predicts highly accurate simulation results by use of machine learning. The information processor 100 is used in, for example, designing an industrial component. The information processor 100 may be a client device or server device. The information processor 100 may be referred to, for example, as computer, analyzer, simulation device, design device, or machine learning device.

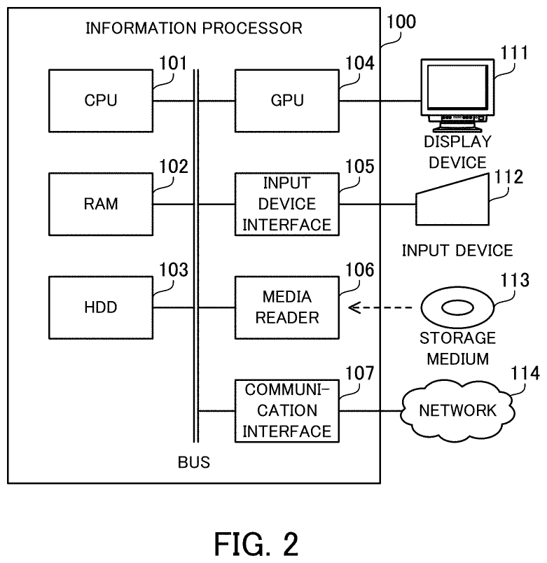

FIG. 2 is a block diagram illustrating an example of hardware of an information processor according to the second embodiment.

The information processor 100 includes a CPU 101, a RAM 102, an HDD 103, a GPU 104, an input device interface 105, a media reader 106, and a communication interface 107, which are individually connected to a bus. The CPU 101 corresponds to the processing unit 12 of the first embodiment. The RAM 102 or the HDD 103 corresponds to the storing unit 11 of the first embodiment.

The CPU 101 is a processor configured to execute program instructions. The CPU 101 reads out at least part of programs and data stored in the HDD 103, loads them into the RAM 102, and executes the loaded programs. Note that the information processor 100 may include two or more processors. The term “multiprocessor”, or simply “processor”, may be used to refer to a set of processors.

The RAM 102 is volatile semiconductor memory for temporarily storing therein programs to be executed by the CPU 101 and data to be used by the CPU 101 for its computation. The information processor 100 may be provided with a different type of volatile memory other than RAM.

The HDD 103 is a non-volatile storage device to store therein software programs, such as an operating system (OS), middleware, and application software, and various types of data. The information processor 100 may be provided with a different type of non-volatile storage device, such as flash memory or a solid-state drive (SSD).

The GPU 104 performs image processing in cooperation with the CPU 101. The GPU 104 displays video images on a screen of a display device 111 coupled to the information processor 100. The display device 111 may be a cathode ray tube (CRT) display, a liquid crystal display (LCD), an organic electro-luminescence (OEL) display, or a projector. An output device, such as a printer, other than the display device 111 may also be connected to the information processor 100.

The input device interface 105 receives an input signal from an input device 112 connected to the information processor 100. Various types of input devices may be used as the input device 112, for example, a mouse, a touch panel, or a keyboard. A plurality of types of input devices may be connected to the information processor 100.

The media reader 106 is a device for reading programs and data recorded on a storage medium 113. The storage medium 113 may be, for example, a magnetic disk, an optical disk, or semiconductor memory. Examples of the magnetic disk include a flexible disk (FD) and HDD. Examples of the optical disk include a compact disc (CD) and digital versatile disc (DVD). The media reader 106 copies the programs and data read out from the storage medium 113 to a different storage medium, for example, the RAM 102 or the HDD 103. The read programs may be executed by the CPU 101.

The storage medium 113 may be a portable storage medium and used to distribute the programs and data. In addition, the storage medium 113 and the HDD 103 may be referred to as computer-readable storage media.

The communication interface 107 is connected to a network 114 and communicates with different information processors via the network 114. The communication interface 107 may be a wired communication interface connected to a wired communication device, such as a switch or router, or may be a wireless communication interface connected to a wireless communication device, such as a base station or access point.

Next described is a flow of a structural analysis simulation.

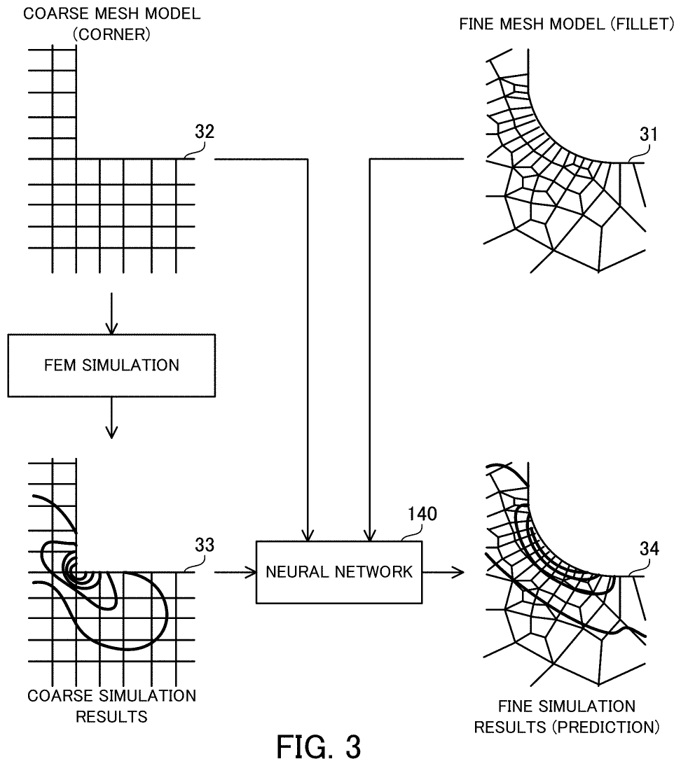

FIG. 3 illustrates an example of stress prediction using a neural network.

The second embodiment considers angles of an industrial component as sites for highly accurate stress calculation. The term “corner” herein sometimes refers to a sharp angle with a vertex, where the angle lies between 0 and 180 degrees. When an external force is applied to an industrial component including such corners, stress concentration may be observed, which is localized stress considerably higher than stress at other locations on the industrial component. In view of this, in designing an industrial component, angles may be formed into fillets, instead of corners, to alleviate stress concentration. A fillet is a smooth and curved surface of a constant radius, without a vertex. Stress in the vicinity of a fillet is expected to be lower compared with the case of a corner.

One strategy of calculating stress at a fillet is to create a fine mesh model 31 which highly accurately represents the shape of the fillet and then run a FEM simulation using the fine mesh model 31. Each mesh model here is a geometrical model representing the shape of an object with a mesh and includes a plurality of discrete nodes and a plurality of edges connecting them. In mesh models, space where an object lies is divided into elements, which are small regions enclosed by nodes and edges. In the second embodiment, the elements have triangular facets. Usually, there exists CAD data for an industrial component under design. In view of this, the information processor 100 generates the fine mesh model 31 from the CAD data, for example, using mesh generation software.

However, a FAM simulation using the fine mesh model 31 with a large number of nodes and edges may face high computational complexity and thus take long time to run. Therefore, the information processor 100 runs a FEM simulation using a coarse mesh model 32 in place of the FEM simulation using the fine mesh model 31.

First, the coarse mesh model 32 corresponding to the fine mesh model 31 is created. The coarse mesh model 32 contains a lower number of nodes and edges than the fine mesh model 31. Therefore, the coarse mesh model 32 has reduced accuracy of shape representation compared with the fine mesh model 31. As a result, the coarse mesh model 32 may fail to fully reproduce the curve of a fillet and represent the shape of an angle as a corner rather than a fillet.

The information processor 100 runs a FEM simulation using the coarse mesh model 32 and generates coarse simulation results 33. For example, the information processor 100 assigns variables to nodes of the coarse mesh model 32, and generates a coefficient matrix representing the relationships between the nodes based on a governing equation modelling a physical law of structural dynamics. The information processor 100 finds an approximate solution to a system of equations by an iterative method using the coefficient matrix. The coarse simulation results 33 include stress in the vicinity of a corner which is a representation of the shape of an angle.

The information processor 100 generates input data for a neural network 140 which is built in advance through machine learning. The input data is a tensor that includes a feature aspect related to the stress indicated by the coarse simulation results 33, feature aspects related to the shape of the corner represented by the coarse mesh model 32, and a feature aspect related to the shape of the fillet represented by the fine mesh model 31. The neural network 140 predicts stress in the vicinity of the fillet. Herewith, fine simulation results 34 including the predicted stress at the fillet are generated.

The stress indicated by the fine simulation results 34 corresponds to stress that would be obtained when a FEM simulation is performed using the fine mesh model 31. Therefore, the fine simulation results 34 exhibit higher accuracy than the coarse simulation results 33. On the other hand, the FEM simulation using the coarse mesh model 32 needs lower computational effort than when using the fine mesh model 31. In addition, producing the prediction by the neural network 140 takes sufficiently low computational cost. As a result, the structural analysis simulation takes less time to be implemented.

Note that highly accurate calculation of stress may be focused on critical locations where stress concentration is likely to occur, such as angles. For outside of the critical locations, stress calculated from the coarse mesh model 32 may be used. In light of these considerations, the information processor 100 calculates stress distribution across the whole object using the coarse mesh model 32, and then converts stress at each corner within the object into stress at a fillet using the neural network 140. The neural network 140 thus calculates predicted stress for each fillet.

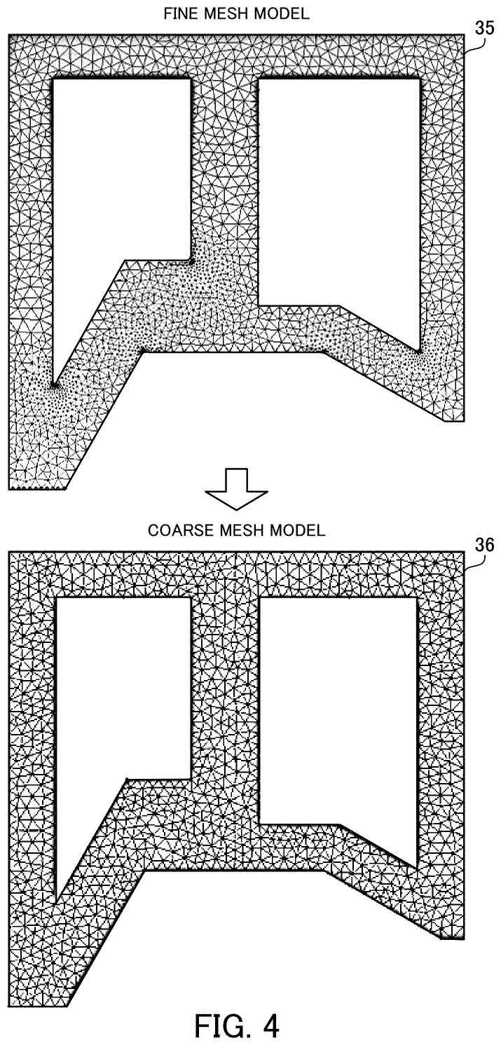

FIG. 4 illustrates examples of fine and coarse mesh models.

A fine mesh model 35 corresponds to the aforementioned fine mesh model 31 while a coarse mesh model 36 corresponds to the aforementioned coarse mesh model 32. The fine mesh model 35 and the coarse mesh model 36 represent the shape of the same industrial component. In the fine mesh model 35 and the coarse mesh model 36, all elements have triangular facets.

This industrial component has two holes and one notch. The industrial component also has ten exterior angles greater than 0° and less than 180°. Among the ten angles, one angle is 45°, one angle is 60°, six angles are 90°, one angle is 120°, and one angle is 150°. The shape of each angle is a fillet in the fine mesh model 35 while the shape of each angle is a corner in the coarse mesh model 36. Therefore, the fine mesh model 35 has a significantly higher number of nodes and edges around the angles than the coarse mesh model 36.

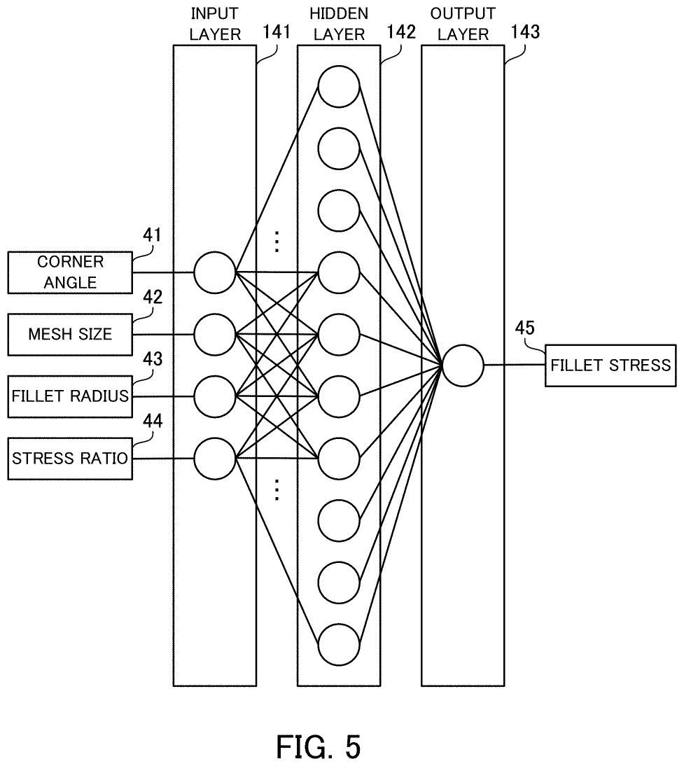

FIG. 5 illustrates an example of a structure of a neural network.

The neural network 140 includes an input layer 141, a hidden layer 142, and an output layer 143. The hidden layer 142 is located between the input layer 141 and the output layer 143. The input layer 141 includes four nodes. The hidden layer 142 includes ten nodes. The output layer 143 includes one node. Each node in the input layer 141 is connected by edges to the ten nodes in the hidden layer 142. Each node in the hidden layer 142 is connected to the node in the output layer 143.

The four nodes in the input layer 141 correspond to a corner angle 41, a mesh size 42, a fillet radius 43, and a stress ratio 44. The one node in the output layer 143 corresponds to a fillet stress 45. The corner angle 41, the mesh size 42, the fillet radius 43, and the stress ratio 44 are input data corresponding to explanatory variables. The fillet stress 45 is output data corresponding to a target variable. In machine learning processing for building the neural network 140, the fillet stress 45 obtained from the output layer 143 is compared with labeled training data which indicates a correct fillet stress.

The corner angle 41 is the angle measure of one corner included in the coarse mesh model 32. The mesh size 42 is the size of the mesh in the vicinity of the corner within the coarse mesh model 32. The fillet radius 43 is the radius of curvature of a fillet included in the fine mesh model 31, corresponding to the corner. The stress ratio 44 is the ratio of the magnitudes of stresses at a vertex of the corner, acting in different directions. For example, the stress ratio 44 is the ratio of the magnitude of the horizontal stress near the corner to the magnitude of the vertical stress beyond the vertex on the other side.

The corner angle 41 and the mesh size 42 correspond to feature aspects of the coarse mesh model 32. The fillet radius 43 corresponds to a feature aspect of the fine mesh model 31. The stress ratio 44 corresponds to a feature aspect of the coarse simulation results 33. The fillet stress 45 is a predicted stress at the fillet corresponding to the aforementioned corner.

Edges included in the neural network 140 have weights associated with them. In generation of output data, the product of the output value of a node and the weight of an edge is transmitted to a node in the following layer along the edge. The node in the following layer inputs the sum of products received into a predetermined activation function to calculate its own output value. Thus, forward computation proceeds in the forward direction from the input layer 141 to the output layer 143 to thereby generate the output data from the input data.

In the machine learning processing, weights of edges are determined by backward propagation. The backward propagation evaluates an error between an output of the neural network 140 and labeled training data, and calculates an error gradient representing the change in the error observed when the weight of each edge is changed only slightly. The backward propagation updates the weight of each edge based on the calculated error gradient and a predetermined learning rate. The weights of individual edges are sequentially updated by the backward computation proceeding in the backward direction from the output layer 143 to the input layer 141. That is, error information propagates through the neural network 140 in the opposite direction to the direction in which the forward computation proceeds.

The information processor 100 generates training data including input data and labeled training data, and determines weights of the neural network 140 using the generated training data. In order to generate the training data, the information processor 100 enumerates candidate values for each of the corner angle 41, the mesh size 42, the fillet radius 43, and the stress ratio 44. The information processor 100 generates a plurality of simulation conditions with different combination patterns of the corner angle 41, the mesh size 42, the fillet radius 43, and the stress ratio 44. The information processor 100 generates, for each simulation condition, a fine mesh model sample satisfying the condition and runs a FEM simulation to thereby obtain a correct answer of the fillet stress 45.

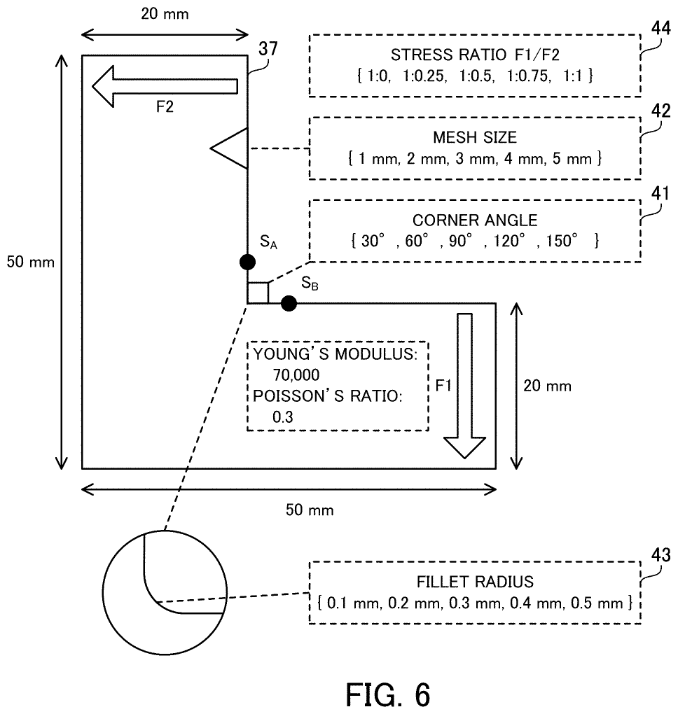

FIG. 6 illustrates examples of parameters associated with a corner and a fillet.

A mesh model 37 is a sample representing one corner or fillet. The mesh model 37 has the dimensions of 50 mm on the left side, 50 mm on the lower side, 20 mm on the upper side, and 20 mm on the right side. In addition, the length between the upper side and a corner vertex is 30 mm, and the length between the right side and the corner vertex is 30 mm.

The candidate values for the corner angle 41 are 30°, 60°, 90°, 120°, and 150°. The candidate values for the mesh size 42 are 1 mm, 2 mm, 3 mm, 4 mm, and 5 mm. The mesh size 42 corresponds, for example, to the length of one side of each element. The candidate values for the fillet radius 43 are 0.1 mm, 0.2 mm, 0.3 mm, 0.4 mm, and 0.5 mm. The larger the fillet radius 43, the gentler the angle curves.

The candidate values for the stress ratio 44 are 1 to 0, 1 to 0.25, 1 to 0.5, 1 to 0.75, and 1 to 1. The stress ratio 44 is a load condition indicating a pattern of force applied to the angle. In general, the stress ratio 44 involves nodal Mises stresses S_{A} and S_{B} at two locations on mutually different sides across the angle, and is defined as a ratio of the lower one of the two values S_{A} and S_{B} to the higher one. According to the second embodiment, the stress ratio 44 is defined as F1/F2, where F1 is force applied to the right of the angle in a direction from the upper side to the lower side, and F2 is force applied above the angle in a direction from the right side to the left side and perpendicular to F1. In addition, Young's modulus and Poisson's ratio, which are material parameters representing the elasticity of an object, are set to 70000 and 0.3, respectively.

Thus, in generation of training data, the information processor 100 sets five candidate values for each of the corner angle 41, the mesh size 42, the fillet radius 43, and the stress ratio 44. The information processor 100 exhaustively generates all combination patterns of these candidate values to thereby generate 625 simulation conditions. The information processor 100 runs a FEM simulation using a fine mesh model according to each of the 625 simulation conditions and calculates correct fillet stresses. Note however that fillet stresses may be measured on trial components produced, instead of running the FEM simulations.

The information processor 100 builds the neural network 140 through machine learning based on the generated training data. Predicting the fine simulation results 34 using the neural network 140 speeds up the structural analysis simulation.

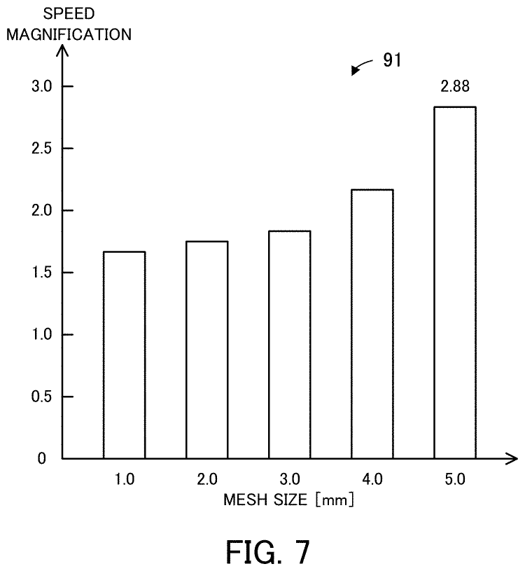

FIG. 7 is a graph illustrating examples of speed magnification of stress prediction.

The horizontal axis of a graph 91 represents mesh size of the coarse mesh model while the vertical axis represents speed magnification. The numerator of the speed magnification is the run-time of a FEM simulation using a fine mesh model. The denominator of the speed magnification is the sum of the run-time of a FEM simulation using a coarse mesh model and the run-time of fillet stress prediction using the neural network 140. A higher speed magnification indicates a greater effect in reducing the total run-time.

As illustrated in the graph 91, the speed magnification is: about 1.7 when the mesh size is 1 mm; about 1.8 when the mesh size is 2 mm; about 1.9 when the mesh size is 3 mm; about 2.2 when the mesh size is 4 mm; and 2.88 when the mesh size is 5 mm. In this manner, the fillet stress prediction using the neural network 140 is faster than the numerical analysis approach using a FEM simulation only. In addition, a larger mesh size leads to a greater speed-up.

Next described is creation of the coarse mesh model 32.

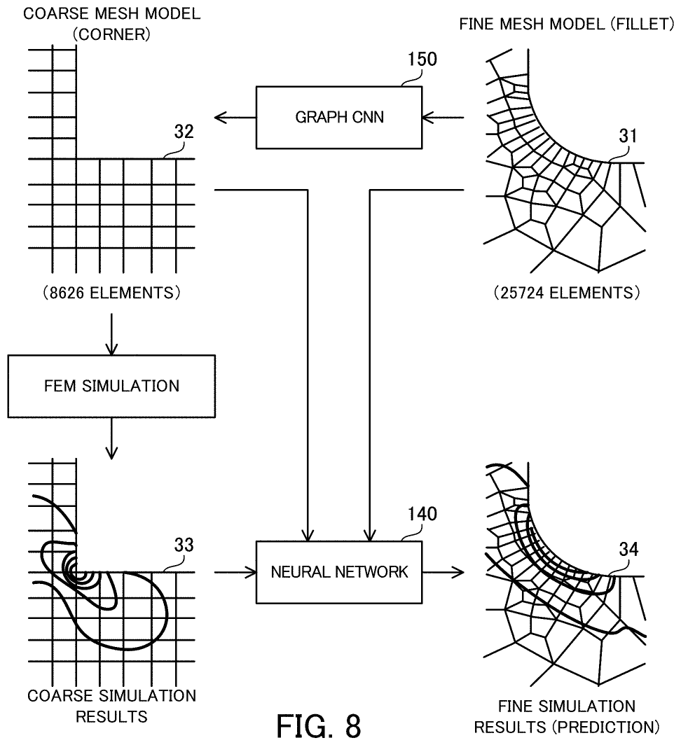

FIG. 8 illustrates a second example of stress prediction using a neural network.

If the fine mesh model 31 already exists, the coarse mesh model 32 is created based on the fine mesh model 31. Note however that manual creation of the coarse mesh model 32 causes the user to assume a heavy burden. Especially when the industrial component includes a large number of fillets, the task of modifying each fillet into a corner puts a great strain on the user. In addition, the mesh pattern of the coarse mesh model 32 corresponding to the fine mesh model 31 is not always obvious from the fine mesh model 31. Therefore, there is a risk for creating the coarse mesh model 32 of low quality.

In view of the above, the information processor 100 automatically builds the coarse mesh model 32 from the fine mesh model 31 by use of a graph convolutional neural network (CNN) 150. The graph CNN 150 is a CNN generated through machine learning. CNNs are multi-layer neural networks that perform convolution, which is a type of product-sum operations.

Note however that, unlike in the case of commonly used CNNs, the graph CNN 150 handles mesh data in place of image data. Commonly used CNNs calculate features of pixels arranged in a grid according to adjacency relationships between the pixels. On the other hand, the graph CNN 150 calculates features of edges included in a mesh model according to connection relationships between the edges. The graph CNN 150 may be referred to as mesh CNN.

The information processor 100 feeds information on edges included in the fine mesh model 31 to the graph CNN 150. The graph CNN 150 calculates a feature of each edge, and removes some edges based on the calculated edge features. The graph CNN 150 determines, based on the features of the remaining edges, the class (type) of an object represented by the fine mesh model 31. The information processor 100 extracts, from the graph CNN 150, intermediate data generated in the process of the class determination, to thereby generate the coarse mesh model 32.

The coarse mesh model 32 generated using the graph CNN 150 includes important edges representing fundamental features of the fine mesh model 31. For example, the information processor 100 generates the coarse mesh model including 8626 elements from the fine mesh model 31 including 25724 elements.

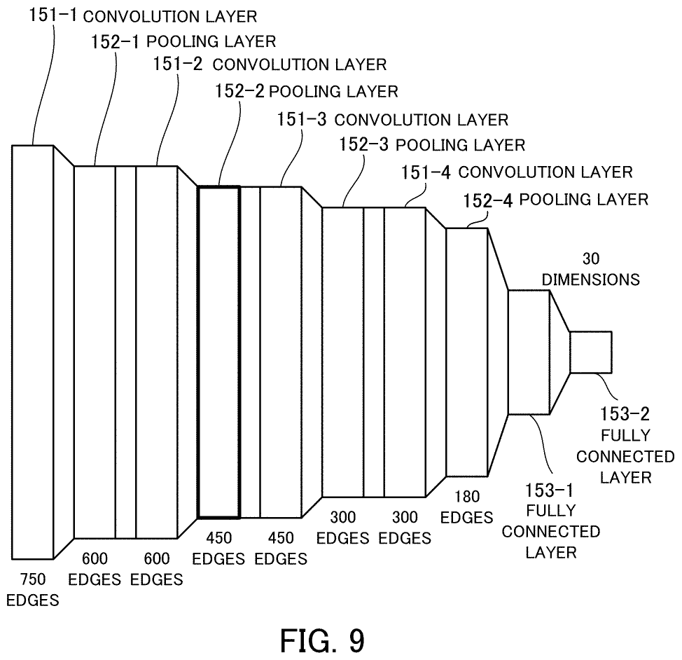

FIG. 9 illustrates an example of a structure of a graph CNN.

The graph CNN 150 includes four convolution layers 151-1 to 151-4, four pooling layers 152-1 to 152-4, and two fully connected layers 153-1 and 153-2. The convolution layer 151-1 is followed by the pooling layer 152-1, followed by the convolution layer 151-2, followed by the pooling layer 152-2, followed by the convolution layer 151-3, followed by the pooling layer 152-3, followed by the convolution layer 151-4, followed by the pooling layer 152-4, followed by the fully connected layer 153-1, followed by the fully connected layer 153-2.

The graph CNN 150 processes 750 linked edges as one batch. The graph CNN 150 receives initial features of the 750 edges. The feature of each edge is a 5-dimensional vector. The graph CNN 150 also outputs a class vector indicating a class of the object represented by the input data. The class vector is a 30-dimensional vector. Each dimension of the class vector corresponds to one class. The class vector lists the probability that the object represented by the input data belongs to each of the thirty classes. The class vector indicates that the input data is classified into a class with the maximum probability.

The convolution layers 151-1 to 151-4 update the feature of each edge by convolution operations. The feature of a given edge is updated in such a manner as to incorporate therein the features of neighboring edges adjacent to the edge. The number of edges remains the same before and after each of the convolution layers 151-1 to 151-4.

The pooling layers 152-1 to 152-4 remove some edges by pooling operations. Each of the pooling layers 152-1 to 152-4 determines insignificant edges based on the edge features calculated by its preceding convolution layer and then removes them. The number of edges to be removed is a hyperparameter defined before machine learning. When a given edge is removed, nodes at either end of the edge are contracted. In addition, the features of neighboring edges adjacent to the edge are updated.

The convolution layer 151-1 outputs 750 edge features. The pooling layer 152-1 removes 150 edges out of the 750 edges, and outputs 600 edge features. The convolution layer 151-2 outputs 600 edge features. The pooling layer 152-2 removes 150 edges out of the 600 edges, and outputs 450 edge features. The convolution layer 151-3 outputs 450 edge features. The pooling layer 152-3 removes 150 edges out of the 450 edges, and outputs 300 edge features. The convolution layer 151-4 outputs 300 edge features. The pooling layer 152-4 removes 120 edges out of the 300 edges, and outputs 180 edge features.

The fully connected layer 153-1 generates, from the 180 edge features, a vector whose dimensions are greater than 30. The fully connected layer 153-2 generates a 30-dimensional class vector from the vector output from the fully connected layer 153-1 and outputs the class vector.

Note however that, in the structural analysis simulation, the information processor 100 does not use the very class vector output from the graph CNN 150. The information processor 100 feeds the fine mesh model 31 to the graph CNN 150 and extracts the output of the pooling layer 152-2. The output of the pooling layer 152-2 is information indicating 450 edges significant for the class determination amongst the 750 edges. The information processor 100 generates a set of edges indicated by the output of the pooling layer 152-2 as the coarse mesh model 32.

Note that, according to the second embodiment, four pooling layers are provided; however, the number of pooling layers may be changed. In addition, according to the second embodiment, the information processor 100 extracts the output of the second pooling layer; however, the output of the third pooling layer or a different pooling layer may be extracted instead. The pooling layer to be used may be determined during machine learning processing for generating the graph CNN 150 or selected when the coarse simulation results 33 are generated. The pooling layer to be used may be specified by the user.

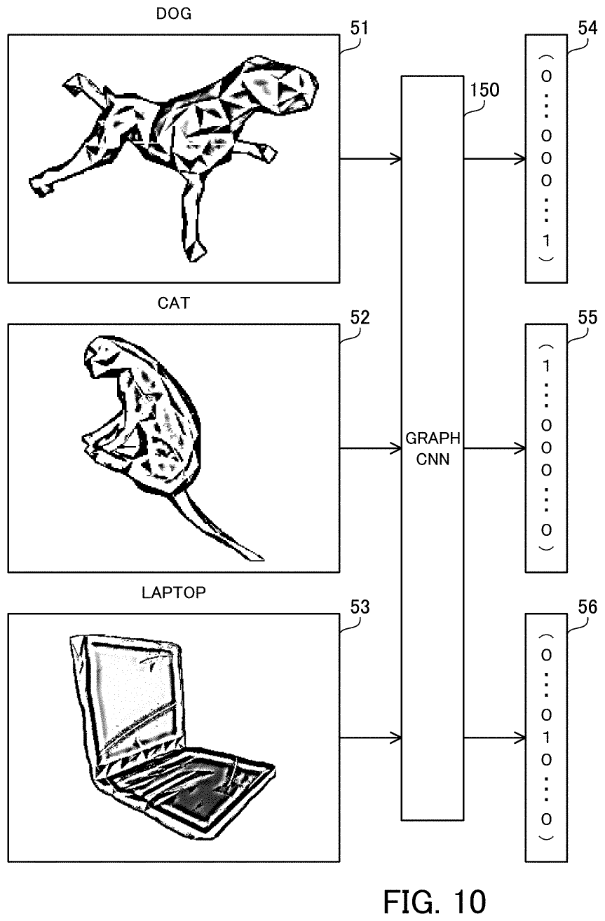

FIG. 10 illustrates examples of inputs and outputs of a graph CNN.

The information processor 100 generates training data for the graph CNN 150 separately from the training data for the neural network 140 and then runs machine learning. The training data is generated from mesh model samples for each of which a training label is provided. Each sample represents the shape of an object which belongs to one of the 30 classes. The training label indicates a correct class to which the object belongs.

For example, mesh models 51, 52, and 53 are sample mesh models. The mesh model 51 represents the shape of a dog and is given a training label indicating that the class is Dog. The mesh model 52 represents the shape of a cat and is given a training label indicating that the class is Cat. The mesh model 53 represents the shape of a laptop computer and is given a training label indicating that the class is Laptop.

The information processor 100 generates input data by extracting edges from the mesh model 51, and also generates labeled training data 54 in which a dimension corresponding to Dog is 1 while other dimensions are all 0's. Similarly, the information processor 100 generates input data by extracting edges from the mesh model 52, and also generates labeled training data 55 in which a dimension corresponding to Cat is 1 while other dimensions are all 0's. The information processor 100 generates input data by extracting edges from the mesh model 53, and also generates labeled training data 56 in which a dimension corresponding to Laptop is 1 while other dimensions are all 0's.

In the machine learning processing of the graph CNN 150, the information processor 100 performs an error propagation process similar to one used in the above-described neural network 140. The information processor 100 feeds input data corresponding to the mesh model 51 to the graph CNN 150, evaluates an error of the output with respect to the labeled training data 54, and then updates weights of the graph CNN 150. The error is, for example, a Euclidean distance between the two vectors.

The information processor 100 also feeds input data corresponding to the mesh model 52 to the graph CNN 150, evaluates an error of the output with respect to the labeled training data 55, and then updates the weights of the graph CNN 150. In addition, the information processor 100 feeds input data corresponding to the mesh model 53 to the graph CNN 150, evaluates an error of the output with respect to the labeled training data 56, and then updates the weights of the graph CNN 150.

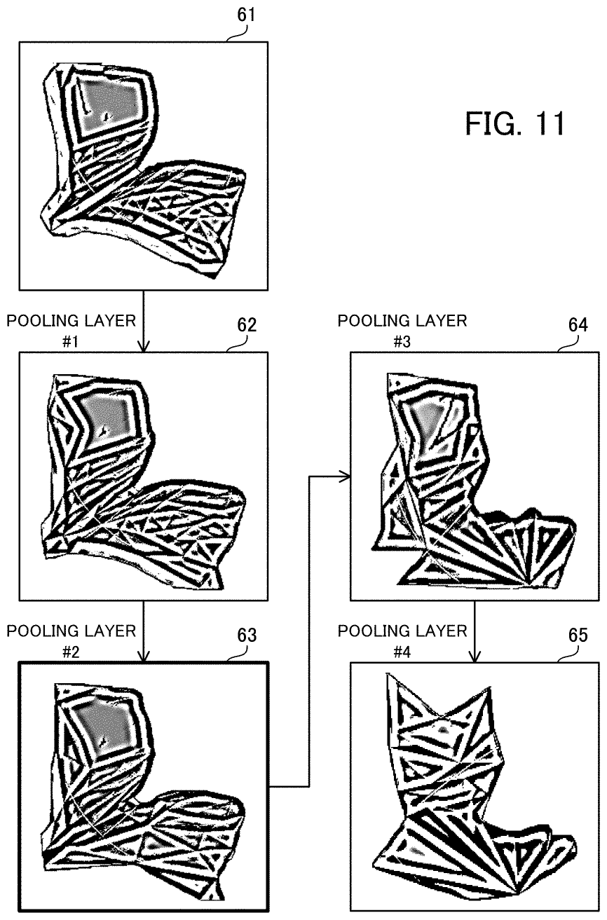

FIG. 11 illustrates an example of stepwise pooling of a mesh model.

According to the above-described graph CNN 150, the fine mesh model 31 is simplified by the pooling layers 152-1 to 152-4 in a step-by-step fashion. The information processor 100 extracts the output of an appropriate pooling layer amongst the pooling layers 152-1 to 152-4 to thereby obtain the coarse mesh model 32 suitable for a FEM simulation. The information processor 100 may ignore a class vector output at the end of the graph CNN 150.

For example, the information processor 100 feeds a mesh model 61 to the graph CNN 150. Then, a mesh model 62 is obtained as the output of the pooling layer 152-1. The mesh model 62 has been simplified with a fewer number of edges compared with the mesh model 61. Subsequently, a mesh model 63 is obtained as the output of the pooling layer 152-2. The mesh model 63 has been simplified with an even fewer number of edges compared with the mesh model 62. Then, a mesh model 64 is obtained as the output of the pooling layer 152-3. The mesh model 64 has been simplified with an even fewer number of edges compared with the mesh model 63. Subsequently, a mesh model 65 is obtained as the output of the pooling layer 152-4. The mesh model 65 has been simplified with an even fewer number of edges compared with the mesh model 64.

In the machine learning processing for building the graph CNN 150, the user may select an appropriate pooling layer by checking the outputs of the pooling layers 152-1 to 152-4. Alternatively, the user may run trial FEM simulations and then select a pooling layer in consideration of the run-time and accuracy of the coarse simulation results 33.

Next described are convolution operations (mesh convolution operations) and pooling operations (mesh pooling operations) of the graph CNN 150. The mesh convolution operations and mesh pooling operations are described, for example, in the following literature: Rana Hanocka, Amir Hertz, Noa Fish, Raja Giryes, Shachar Fleishman, and Daniel Cohen-Or, “MeshCNN: A Network with an Edge”, ACM Transactions on Graphics, Volume 38, Issue 4, Article No. 90, July 2019.

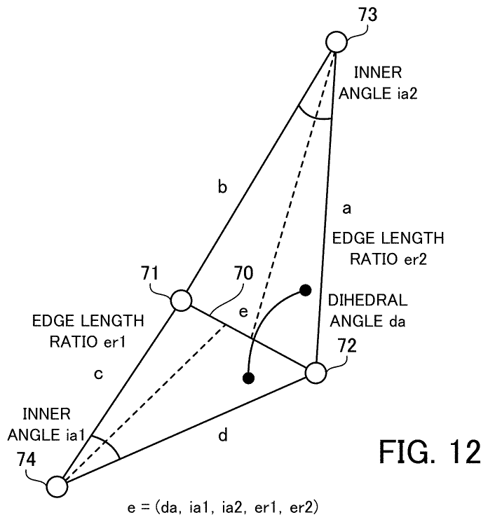

FIG. 12 illustrates examples of edge feature parameters.

First, the information processor 100 calculates a feature of each edge included in an input mesh model (i.e., an initial edge feature of each edge). An edge 70 connects nodes 71 and 72. The edge 70 belongs to the facet of a triangle connecting three nodes 71, 72, and 73. The edge 70 also belongs to the facet of a triangle formed by three nodes 71, 72, and 74. Thus, one edge belongs to two facets.

The information processor 100 calculates an edge feature e corresponding to the edge 70. The edge feature e is a 5-dimensional vector. The first dimension indicates a dihedral angle which is an angle between the two facets to which the edge 70 belongs. The second dimension indicates an inner angle at a vertex of one of the facets. For example, the second dimension is an inner angle at the node 74. The third dimension indicates an inner angle at a vertex of the other facet. For example, the third dimension is an inner angle at the node 73.

The fourth dimension is an edge length ratio which is a ratio between the base and the height of one of the facets, i.e., a ratio between the length of the edge 70 and the length of the perpendicular drawn from the vertex of one of the facets (e.g., the node 74) to the edge 70. The fifth dimension is an edge length ratio which is a ratio between the base and the height of the other facet, i.e., a ratio between the length of the edge 70 and the length of the perpendicular drawn from the vertex of the other facet (e.g., the node 73) to the edge 70.

The convolution layers 151-1 to 151-4 individually perform a mesh convolution operation on each remaining edge to thereby update the edge feature. The mesh convolution operation uses edge features of four neighboring edges included in the two facets to which the edge-of-interest belongs. Therefore, the edge features of the five edges are processed as one set.

Processing of the convolution layer 151-1 is described below as an example. According to the above-described definition of an edge feature, the convolution layer 151-1 acquires the edge feature e of the edge 70. The convolution layer 151-1 also acquires an edge feature a of the neighboring edge between the nodes 72 and 73, an edge feature b of the neighboring edge between the nodes 71 and 73, an edge feature c of the neighboring edge between the nodes 71 and 74, and an edge feature d of the neighboring edge between the nodes 72 and 74.

Note here that the sequence of the four neighboring edges is defined in an anti-clockwise direction with respect to the edge 70. Note however that, priorities between the two facets are not uniquely determined in the mesh model and there are, therefore, two possible sequences of the four edge features, i.e., (a, b, c, d) and (c, d, a, b). Then, in order to ensure invariance of the mesh convolution operations, the convolution layer 151-1 converts the edge features a, b, c, and d into edge features e₁, e₂, e₃, and e₄, as defined by Equation (1) below. The edge features e₁, e₂, e₃, and e₄ are symmetric.

(e₁,e₂,e₃,e₄)=(|a−c|,a+c,|b−d|,b+d) (1)

The convolution layer 151-1 updates the edge feature e of the edge 70 based on the edge feature e and the edge features e₁, e₂, e₃, and e₄ of the four neighboring edges, as defined by Equation (2) below. In Equation (2), k₀, k₁, k₂, k₃, and k₄ are kernel coefficients determined by machine learning and represent weights of the five edge features. Note that the edge features e, e₁, e₂, e₃, and e₄ are 5-dimensional vectors. The kernel coefficients k₀, k₁, k₂, k₃, and k₄ may be common among the five dimensions, or different for each dimension.

$$e = {k}_{0} \cdot e + {\sum }_{j = 1}^{4} {k}_{j} \cdot {e}_{j} \qquad ( 2 )$$

The above-described mesh convolution operations may be implemented as matrix operations. For example, the convolution layer 151-1 generates a tensor with a size of N_{c}×Nₑ×5. N_{c} is the number of dimensions of each edge feature, i.e., N_{c}=5. Nₑ is the number of edges-of-interest in a single mesh convolution operation and, for example, Nₑ=1. “5” at the end means the total sum of the edges-of-interest and their neighboring edges. The convolution layer 151-1 also holds a kernel matrix where kernel coefficients are arranged. The convolution layer 151-1 performs general matrix multiplication (GeMM) that calculates the dot product between the aforementioned tensor and the kernel matrix. Note that provision of a plurality of kernel matrices may allow for calculation of a plurality of edge features for each edge.

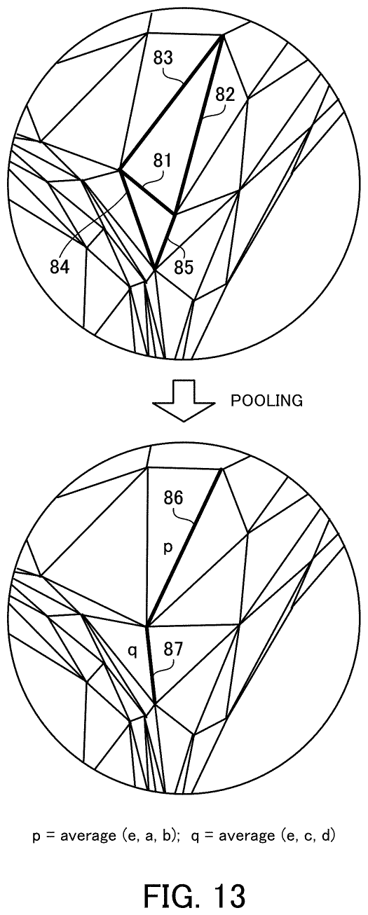

FIG. 13 illustrates an example of edge removal by pooling.

Each of the pooling layers 152-1 to 152-4 removes a predetermined number of edges (e.g., 150 edges) based on edge features calculated in its preceding convolution layer. Processing of the pooling layer 152-1 is described below as an example.

The pooling layer 152-1 calculates, for each edge, the L2 norm of the edge feature. The L2 norm is the square root of sum of squares, i.e., the Euclidean distance from the zero vector which is the origin of the vector space. The pooling layer 152-1 selects a predetermined number of edges with priority to those with smaller L2 norms. The edges selected here are those of low importance. The pooling layer 152-1 removes each of the selected edges and contracts nodes at either end of the edge into a new node. The new node is located, for example, at the halfway point between the nodes on both ends. With this contraction, two out of the four neighboring edges disappear. The pooling layer 152-1 updates edge features of the remaining two neighboring edges.

Assume, for example, that edges 81, 82, and 83 form one facet and edges 81, 84, and 85 form one facet. The edge 81 corresponds to the edge 70 cited above, and has the edge feature e. The edge 82 has the feature a, the edge 83 has the edge feature b, the edge 84 has the edge feature c, and the edge 85 has the edge feature d.

When the L2 norm of the edge feature e is the smallest, the pooling layer 152-1 removes the edge 81. Then, the edges 82 and 83 are integrated into an edge 86 while the edges 84 and 85 are integrated into an edge 87. In this manner, when one inconsequential edge is selected, five edges are integrated into two edges and two facets disappear.

The pooling layer 152-1 calculates an edge feature p of the edge 86 and an edge feature q of the edge 87. The edge feature p is a mean vector of the edge features e, a, and b of the edges 81, 82, and 83 forming the one facet. The edge feature q is a mean vector of the edge features e, c, and d of the edges 81, 84, and 85 forming the other facet.

Note that the pooling layer 152-1 may select edges to be removed in consideration of distribution of nodes or edges across the input mesh model. For example, the pooling layer 152-1 detects, from the input mesh model, regions in which the density of nodes or edges exceeds a threshold. Then, the pooling layer 152-1 selects an edge with the smallest L2 norm from each of the detected regions and removes it. In this case, the pooling layer 152-1 may leave edges included in regions of low density even if their L2 norms are small.

Next described are functions and processing procedures of the information processor 100. Note that the information processor 100 according to the second embodiment performs both machine learning processing and stress prediction; however, different information processors may separately handle the machine learning processing and the stress prediction. In this case, a learning model is transmitted from one information processor to the other.

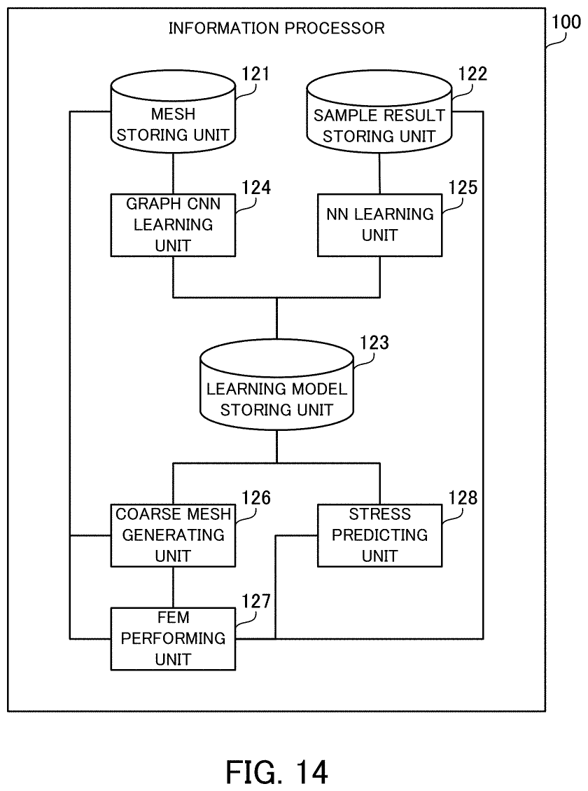

FIG. 14 is a block diagram illustrating examples of functions of the information processor.

The information processor 100 includes a mesh storing unit 121, a sample result storing unit 122, and a learning model storing unit 123. These storing units are implemented, for example, using the RAM 102 or the HDD 103. The information processor 100 also includes a graph CNN learning unit 124, an NN learning unit 125, a coarse mesh generating unit 126, a FEM performing unit 127, and a stress predicting unit 128. These processing units are implemented, for example, using the CPU 101 or the GPU 104 and programs.

The mesh storing unit 121 stores therein mesh models. The stored mesh models include samples to be used for the machine learning processing of the graph CNN 150. The stored mesh models also include samples for generating labeled training data for the neural network 140. In addition, the stored mesh models include the fine mesh model 31 which is a target for stress prediction.

The sample result storing unit 122 stores results of FEM simulations to be used for the machine learning processing of the neural network 140. The stored simulation results include fine simulation results generated from samples of fine mesh models. The learning model storing unit 123 stores the neural network 140 and the graph CNN 150 built by the machine learning processing.

The graph CNN learning unit 124 reads, from the mesh storing unit 121, samples such as the mesh models 51, 52, and 53 and generates training data. The graph CNN learning unit 124 uses the generated training data to thereby build the graph CNN 150 by backward propagation. The graph CNN learning unit 124 stores the generated graph CNN 150 in the learning model storing unit 123.

The NN learning unit 125 reads simulation results of samples from the sample result storing unit 122 and generates training data. The NN learning unit 125 uses the generated training data to thereby build the neural network 140 by backward propagation. The NN learning unit 125 stores the generated neural network 140 in the learning model storing unit 123.

The coarse mesh generating unit 126 reads the fine mesh model 31 from the mesh storing unit 121 and reads the graph CNN 150 from the learning model storing unit 123. The coarse mesh generating unit 126 generates input data from the fine mesh model 31 and feeds the input data to the graph CNN 150. The coarse mesh generating unit 126 extracts the output of the pooling layer 152-2 and generates the coarse mesh model 32.

In the machine learning processing, the FEM performing unit 127 reads samples of fine mesh models from the mesh storing unit 121. Using these samples, the FEM performing unit 127 implements an iterative numerical analysis. The FEM performing unit 127 then generates fine simulation results representing calculated stresses and then stores them in the sample result storing unit 122.

In the stress prediction, the FEM performing unit 127 receives the coarse mesh model 32 from the coarse mesh generating unit 126. Using the coarse mesh model 32, the FEM performing unit 127 implements an iterative numerical analysis. The FEM performing unit 127 generates the coarse simulation results 33 representing calculated stress and transmits them to the stress predicting unit 128.

The stress predicting unit 128 reads the neural network 140 from the learning model storing unit 123 and receives the coarse simulation results 33 from the FEM performing unit 127. The stress predicting unit 128 generates input data using the coarse simulation results 33 and feeds the input data to the neural network 140 to thereby generate the fine simulation results 34 representing predicted stress. The stress predicting unit 128 outputs the fine simulation results 34. The stress predicting unit 128 may store the fine simulation results 34 in the HDD 103, display them on the display device 111, or transmit them to a different information processor.

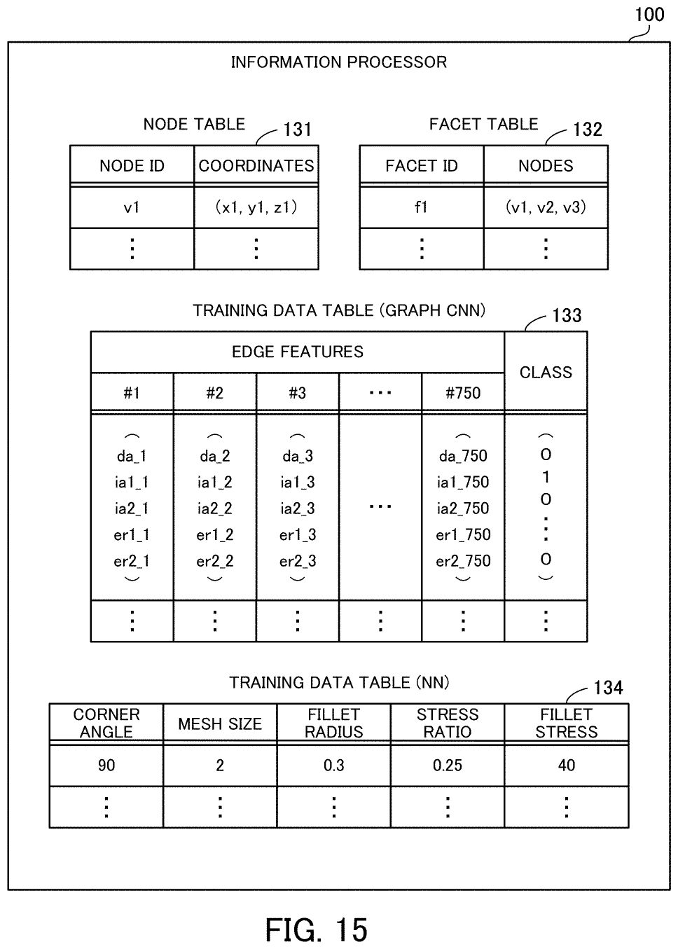

FIG. 15 illustrates examples of structures of mesh data and training data.

The mesh storing unit 121 stores therein, for each mesh model, a node table 131 and a facet table 132. The node table 131 includes, for each of a plurality of nodes, a node identifier for identifying the node and three-dimensional coordinates for specifying the location of the node. The facet table 132 includes, for each of a plurality of facets, a facet identifier for identifying the facet and node identifiers of three nodes forming the facet.

The graph CNN learning unit 124 generates a training data table 133. The training data table 133 includes a plurality of records each including edge features of 750 edges and a class vector. The 750 edge features correspond to explanatory variables and input data. The class vector corresponds to a target variable and labeled training data. Each edge feature is a 5-dimensional vector including a dihedral angle, a first inner angle, a second inner angle, a first edge length ratio, and a second edge length ratio. The class vector is a 30-dimensional vector with only one of the dimensions being 1.

The NN learning unit 125 generates a training data table 134. The training data table 134 includes a plurality of records each including a corner angle, a mesh size, a fillet radius, a stress ratio, and fillet stress. The corner angle, the mesh size, the fillet radius, and the stress ratio correspond to explanatory variables and input data. The fillet stress corresponds to a target variable and labeled training data. The corner angle, the mesh size, the fillet radius, and the stress ratio are provided by the user as 625 combinations of simulation conditions. The fillet stress is calculated by the FEM performing unit 127.

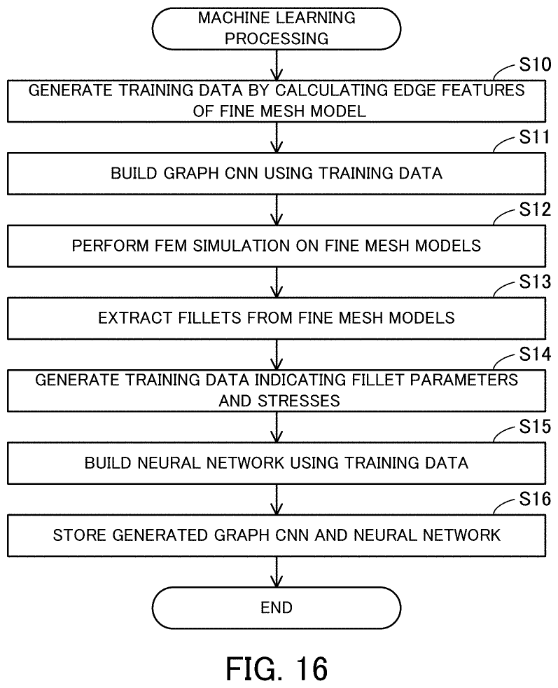

FIG. 16 is a flowchart illustrating an example of a procedure of the machine learning processing.

(Step S10) The graph CNN learning unit 124 extracts edges from each fine mesh model sample, and calculates, for each edge, the edge feature based on the relationships between the edge-of-interest and its four neighboring edges. The graph CNN learning unit 124 generates input data including edge features of a predetermined number of linked edges. The graph CNN learning unit 124 generates a class vector serving as labeled training data from the label of each fine mesh model sample. The graph CNN learning unit 124 generates training data where the input data and the labeled training data are associated with each other.

(Step S11) Using the training data generated in step S10, the graph CNN learning unit 124 builds the graph CNN 150 by backward propagation.

(Step S12) With respect to each of the aforementioned 625 combinations of simulation conditions, the FEM performing unit 127 acquires fine mesh model samples satisfying the simulation condition and performs a FEM simulation to generate fine simulation results.

(Step S13) The NN learning unit 125 extracts fillets from the fine mesh model samples. Fillets may be designated by the user. Alternatively, the NN learning unit 125 may use pattern matching to detect fillets.

(Step S14) The NN learning unit 125 generates input data indicating parameters of each fillet based on the simulation conditions of the step S12. The NN learning unit 125 generates labeled training data indicating fillet stresses calculated in step S12. The NN learning unit 125 generates training data where the input data and the labeled training data are associated with each other.

(Step S15) Using the training data generated in step S14, the NN learning unit 125 builds the neural network 140 by backward propagation.

(Step S16) The FEM performing unit 127 stores the graph CNN 150 built in step S11. The NN learning unit 125 stores the neural network 140 built in step S15.

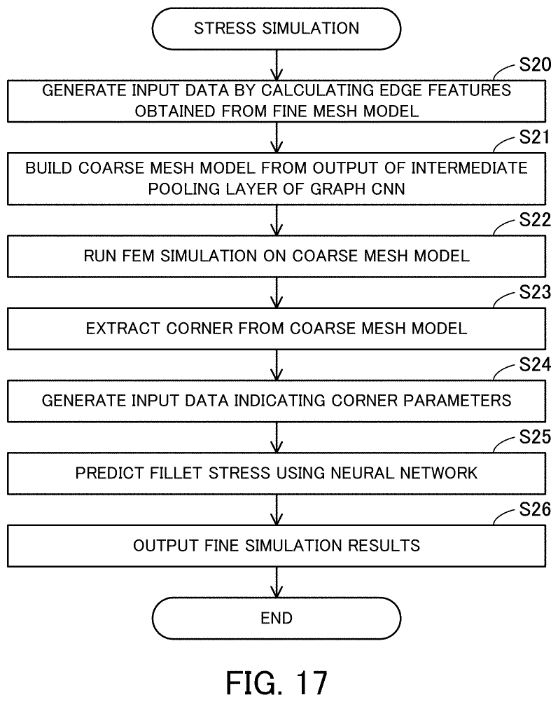

FIG. 17 is a flowchart illustrating an example of a procedure of the stress simulation.

(Step S20) The coarse mesh generating unit 126 acquires the simulation-target fine mesh model 31 and extracts edges therefrom, and then calculates, for each edge, the edge feature based on the relationships between the edge-of-interest and its four neighboring edges. The coarse mesh generating unit 126 generates input data including edge features of a predetermined number of linked edges.

(Step S21) The coarse mesh generating unit 126 feeds the input data to the graph CNN 150. The coarse mesh generating unit 126 extracts the output of the pooling layer 152-2 of the graph CNN 150, and generates the coarse mesh model 32 representing edges output from the pooling layer 152-2.

(Step S22) The FEM performing unit 127 runs a FEM simulation on the coarse mesh model 32 to thereby generate the coarse simulation results 33.

(Step S23) The stress predicting unit 128 extracts a corner from the coarse mesh model 32. The corner to be extracted may be specified by the user. Alternatively, the stress predicting unit 128 may use pattern matching to detect a corner.

(Step S24) The stress predicting unit 128 generates input data including the corner angle 41 and the mesh size 42 indicated by the coarse mesh model 32, the fillet radius 43 indicated by the fine mesh model 31, and the stress ratio 44 indicated by the coarse simulation results 33.

(Step S25) The stress predicting unit 128 feeds the input data of step S24 to the neural network 140 to predict the fillet stress 45. The stress predicting unit 128 generates the fine simulation results 34 including the predicted fillet stress 45.

(Step S26) The stress predicting unit 128 outputs the fine simulation results 34. For example, the stress predicting unit 128 stores the fine simulation results 34 in a non-volatile storage device, such as the HDD 103. For example, the stress predicting unit 128 displays the fine simulation results 34 on the display device 111. For example, the stress predicting unit 128 transmits the fine simulation results 34 to a different information processor.

As described above, the information processor 100 according to the second embodiment generates the fine simulation results 34 indicating fillet stress from the fine mesh model 31 representing a fillet, and outputs the fine simulation results 34. Thus, the information processor 100 yields useful information for designing industrial components. In addition, the information processor 100 uses the coarse mesh model 32 corresponding to the fine mesh model 31 to thereby generate the coarse simulation results 33 by a FEM simulation, and predicts the fine simulation results 34 from the coarse simulation results 33. This reduces computational complexity and run-time compared with the case of generating the fine simulation results 34 directly from the fine mesh model 31 by a FEM simulation.

In addition, the information processor 100 generates the coarse mesh model 32 automatically from the fine mesh model 31 by use of the graph CNN 150. This eases the burden of the user in creating the coarse mesh model 32 separately from the fine mesh model 31, which promotes efficiency in the structural analysis simulation.

The information processor 100 also generates the coarse mesh model 32 based on the output of an intermediate pooling layer included in the graph CNN 150. The graph CNN 150 has been trained to remove inconsequential edges in a stepwise fashion by a plurality of pooling layers. This results in generation of the coarse mesh model 32 of high quality that preserves fundamental features of the fine mesh model 31. As a result, the coarse simulation results 33 and the fine simulation results 34 with improved accuracy are produced.

According to one aspect, it is possible to achieve fast inference of simulation results.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A non-transitory computer-readable recording medium storing therein a computer program that causes a computer to execute a process comprising:
generating, from second mesh data, first mesh data having a smaller number of edges than the second mesh data by use of a first trained model for determining features of mesh data, which includes a plurality of nodes and a plurality of edges connecting the plurality of nodes, by removing some of the plurality of edges from the mesh data;
generating, by running a simulation using the first mesh data, first simulation result data that indicates a physical quantity of an object represented by the first mesh data; and
inferring, from the first mesh data and the first simulation result data and by use of a second trained model, second simulation result data that would be obtained by running the simulation using the second mesh data.

2. The non-transitory computer-readable recording medium according to claim 1, wherein:
the first trained model is a convolutional neural network including a plurality of pooling layers that reduces a number of the plurality of edges in a stepwise fashion, and
the first mesh data is generated based on an output of one of the plurality of pooling layers.

3. The non-transitory computer-readable recording medium according to claim 1, wherein:
the first trained model is a class determination model for determining a class of an object represented by the mesh data, and
the first mesh data is generated by extracting intermediate data from the first trained model during class determination of the second mesh data.

4. The non-transitory computer-readable recording medium according to claim 1, wherein:
the second mesh data is fine mesh data representing a fillet, and the first mesh data is coarse mesh data representing a sharp angle which is sharper than the fillet, and
the second trained model infers second stress acting on the fillet from a first parameter corresponding to a shape of the sharp angle, a second parameter corresponding to first stress acting on the sharp angle, and a third parameter corresponding to a shape of the fillet.

5. An inference method comprising:
generating, by a processor, from second mesh data, first mesh data having a smaller number of edges than the second mesh data by use of a first trained model for determining features of mesh data, which includes a plurality of nodes and a plurality of edges connecting the plurality of nodes, by removing some of the plurality of edges from the mesh data;
generating, by the processor, by running a simulation using the first mesh data, first simulation result data that indicates a physical quantity of an object represented by the first mesh data; and
inferring, by the processor, from the first mesh data and the first simulation result data and by use of a second trained model, second simulation result data that would be obtained by running the simulation using the second mesh data.

6. An information processing apparatus comprising:
a memory configured to store a first trained model for determining features of mesh data, which includes a plurality of nodes and a plurality of edges connecting the plurality of nodes, by removing some of the plurality of edges from the mesh data; and
a processor configured to:
generate, from second mesh data, first mesh data having a smaller number of edges than the second mesh data by use of the first trained model,
generate, by running a simulation using the first mesh data, first simulation result data that indicates a physical quantity of an object represented by the first mesh data, and
infer, from the first mesh data and the first simulation result data and by use of a second trained model, second simulation result data that would be obtained by running the simulation using the second mesh data.
